(19) United States
(12) Patent Application Publication
(10) Pub. No.: US 2020/0401747 A1
(43) Pub. Date: Dec. 24, 2020

(54) SIMULATION METHOD, SIMULATION DEVICE, AND COMPUTER READABLE MEDIUM STORING PROGRAM

(71) Applicant: SUMITOMO HEAVY INDUSTRIES, LTD., Tokyo (JP)

(72) Inventor: Sadanori Ishihara, Kanagawa (JP)

(21) Appl. No.: 17/011,490

(22) Filed: Sep. 3, 2020

Related U.S. Application Data
(63) Continuation of application No. PCT/JP2019/009133, filed on Mar. 7, 2019.

(30) Foreign Application Priority Data
Mar. 19, 2018 (JP) 2018-050919

(51) Int. Cl. G06F 30/25; G06F 30/28

(52) U.S. Cl. CPC G06F 30/25; G06F 30/28

(57) ABSTRACT

Coarse graining is performed in which particles contained in a fluidized bed to be simulated are virtually enlarged to reduce the number of particles, the fluidized bed containing a fluid and a plurality of the particles floating in the fluid. Physical property values relating to the particles and the fluid, and physical quantities defined for the particles and the fluid are converted, under conditions that the dimensionless quantities relating to a flow of the fluidized bed and the dimensionless quantities relating to heat transport do not change before and after the coarse graining. A behavior of the fluidized bed is simulated by using the converted physical property values and physical quantities.

### RELATED APPLICATIONS

The contents of Japanese Patent Application No. 2018-050919, and of International Patent Application No. PCT/JP2019/009133, on the basis of each of which priority benefits are claimed in an accompanying application data sheet, are in their entirety incorporated herein by reference.

### BACKGROUND

### Technical Field

Certain embodiments of the present invention relates to a simulation method, a simulation device, and a computer readable medium storing a program.

### Description of Related Art

A method of analyzing a behavior of a fluidized bed in which solid particles are suspended in a fluid, by coupling the discrete element method (DEM) that analyzes a behavior of particles and the computational fluid dynamics (CFD) that analyzes the flow field of a fluid has been known in the related art. The related art proposes a simulation method that suppresses an increase in calculation time when the number of particles increases. Specifically, a process of enlarging the particles to reduce the number of particles (coarse graining) is performed, the physical property values and physical quantities are converted such that the governing expressions are the same before and after coarse graining, and the fluidized bed after coarse graining is simulated. The related art proposes a method for evaluating heat transport in a fluidized bed.

### SUMMARY

According to one aspect of the present invention, there is provided a simulation method including:

performing coarse graining in which particles contained in a fluidized bed to be simulated are virtually enlarged to reduce the number of particles, the fluidized bed containing a fluid and a plurality of the particles in the fluid;

converting physical property values relating to the particles and the fluid, and physical quantities defined for the particles and the fluid, under conditions that dimensionless quantities relating to a flow of the fluidized bed and dimensionless quantities relating to heat transport do not change before and after the coarse graining; and

simulating a behavior of the fluidized bed by using the converted physical property values and physical quantities.

According to another aspect of the present invention, there is provided a simulation device including:

a simulation condition acquisition unit that acquires of physical property values of a fluid and particles of a fluidized bed to be simulated, and initial conditions of physical quantities defined for the fluid and the particles, the fluidized bed including the fluid and a plurality of the particles in the fluid;

an enlargement ratio acquisition unit that acquires an enlargement ratio for enlarging the particles; and

a calculation unit that converts the initial conditions of the physical quantities and the physical property values which are acquired by the simulation condition acquisition unit, and simulates a behavior of the fluidized bed by using the converted physical property values and physical quantities, under the conditions that dimensionless quantities relating to a flow of the fluidized bed and dimensionless quantities relating to heat transport do not change even when the particles are enlarged.

According to still another aspect of the present invention, there is provided a computer readable medium storing a program that causes a computer to execute a process, the process comprising:

a function of acquiring physical property values of a fluid and particles of a fluidized bed to be simulated and initial conditions of physical quantities defined for the fluid and the particles, the fluidized bed including the fluid and a plurality of the particles in the fluid;

a function of acquiring an enlargement ratio for enlarging the particles; and

a function of converting the acquired initial conditions of the physical quantities and physical property values, and simulating a behavior of the fluidized bed by using the converted physical property values and physical quantities, under the conditions that dimensionless quantities relating to a flow of the fluidized bed and dimensionless quantities relating to heat transport do not change even when the particles are enlarged.

### BRIEF DESCRIPTION OF THE FIGURE

FIG. 1A is a schematic diagram showing an example of a fluidized bed to be simulated, and FIG. 1B is a schematic diagram showing an example of a fluidized bed to be simulated after coarse graining.

FIG. 2 is a chart showing a list of symbols and coarse-graining coefficients used in the present specification, with respect to the physical property values of particles and gases and various physical quantities defined for the particles and the gases.

FIG. 3 is a block diagram of a simulation device according to the present embodiment.

FIG. 4 is a flowchart of the simulation method according to the present embodiment.

FIG. 5 is a perspective view showing a simulation region of the simulation actually performed.

FIG. 6 is a diagram showing the position and temperature of coarse-grained particles obtained by simulation of a coarse-grained fluidized bed in time series.

FIG. 7A and FIG. 7B are graphs showing the time change of the average temperature of the particles obtained from the simulation results.

FIG. 8 is a chart showing a conversion rule applied in a simulation method according to another embodiment.

### DETAILED DESCRIPTION

In the related art, parameters relating to heat transport are not described. That is, the method described in the related art can be applied to the simulation of the behavior of the fluidized bed in the cold state (no change in the temperature, usually at room temperature), but cannot be applied to the simulation of the fluidized bed in the hot state where heat transport can occur. When the method described in the related art is applied to the simulation of the fluidized bed in the hot state, the calculation load increases as the number of particles increases.

It is desirable to provide a simulation method, a simulation device, and a computer readable medium storing a program capable of suppressing an increase in calculation load even when the number of particles increases, in a simulation of a fluidized bed in which heat transport may occur.

The calculation load can be reduced by coarsely graining particles to reduce the number of particles. The results of the simulation regarding the flow and heat transport in the fluidized bed after coarse graining reflect the flow and heat transport status in the fluidized bed before coarse graining. Therefore, the behavior of the fluidized bed before coarse graining can be predicted.

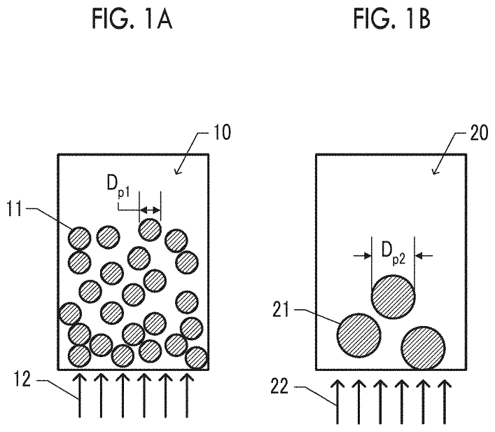

Simulation method and device according to an embodiment will be described with reference to FIGS. 1A to 7B.

FIG. 1A is a schematic diagram showing an example of a fluidized bed to be simulated. A behavior of a fluidized bed formed by disposing a plurality of particles 11 in a region 10 to be simulated and introducing a gas 12 into the region 10 from the lower side to the upper side is simulated. The diameter of the particle 11 is represented by Dₚ₁. In the present embodiment, the calculation load is reduced by enlarging each of the particles 11 and reducing the number thereof (hereinafter referred to as coarse graining).

FIG. 1B is a schematic diagram showing an example of a fluidized bed after coarse graining of a simulation target. The particles 11 are enlarged to obtain virtual particles 21. The virtual particles 21 are disposed in a region 20 to be simulated. The size of the region 20 after coarse graining is the same as the size of the region 10 before coarse graining. The diameter of the virtual particle 21 is represented by Dₚ₂. The enlargement ratio K is defined as the ratio of the diameter of the virtual particle 21 after coarse graining to the diameter of the particle 11 before coarse graining. The enlargement ratio K is defined by the following expression.

Dₚ₂=K·Dₚ₁ (1)

A coarse-grained fluidized bed formed by introducing a gas 22 from the lower side to the upper side into the region 20 in which the coarse-grained particles 21 are disposed is analyzed by coupling the computational fluid dynamics (CFD) and the discrete element method (DEM). During the coarse graining, the physical property values and various physical quantities of the particles 11 and the gas 12 are converted such that the virtual fluidized bed after the coarse graining and the actual fluidized bed before the coarse graining satisfy the similarity rule.

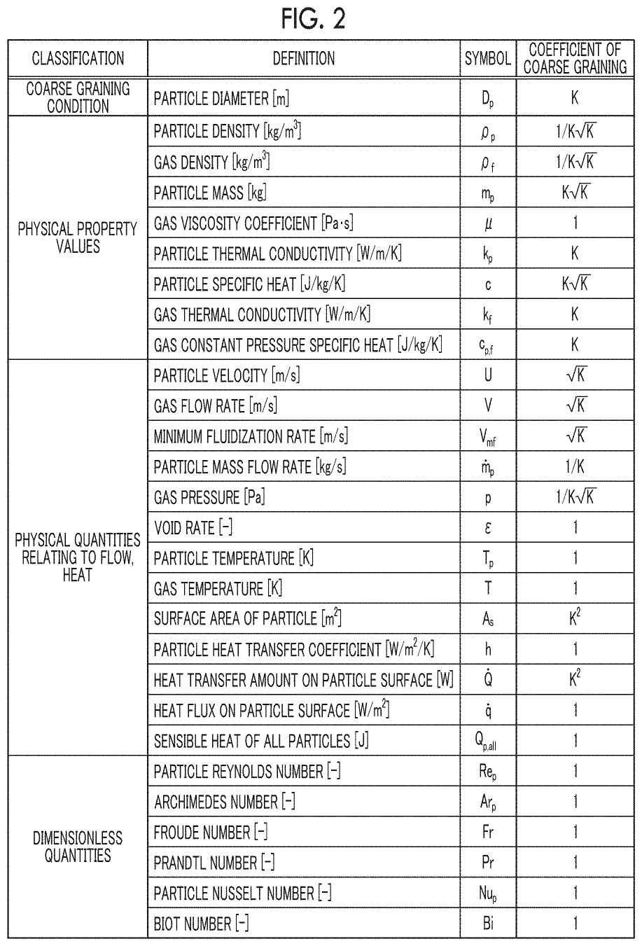

Next, the conversion rule of the physical property values and various physical quantities of the particles 11 and the gas 12 will be described with reference to FIG. 2.

FIG. 2 is a chart showing a list of symbols and coarse-graining coefficients used in the present specification, with respect to the physical property values of particles and gases and various physical quantities defined for the particles and the gases. By multiplying the actual physical property values and physical quantities before coarse graining by the coefficients of coarse graining, the physical property values and physical quantities relating to the fluidized bed after coarse graining are obtained. In the present specification, for example, as shown in Expression (1), a subscript “1” is attached to a symbol representing the physical property values and physical quantities before coarse graining, and a subscript “2” is attached to a symbol representing physical property values and physical quantities after coarse graining.

The dimensionless quantities relating to the flow of the fluidized bed include a particle Reynolds number Reₚ, an Archimedes number Arₚ, and a Froude number Fr. These dimensionless quantities are defined by the following expression.

$${Re}_{p} = \frac{\vert V - U \vert {ρ}_{f} ɛ {D}_{p}}{μ} \\ {Ar}_{p} = \frac{{D}_{p}^{3} {ρ}_{f} ( {ρ}_{p} - {ρ}_{f} ) g}{{μ}^{2}} \\ Fr = \frac{V}{\sqrt{{gD}_{p}}} \qquad ( 2 )$$

Here, g is the gravitational acceleration. Bold letters V and U mean vectors. The void rate ε is defined by the following expression, where M is the total mass of the filled particles and V_{A} is the apparent volume of the region filled with the particles.

$$ϵ = 1 - \frac{M}{{ρ}_{p} {V}_{A}} \qquad ( 3 )$$

Conditions are set such that the particle Reynolds number Reₚ, the Archimedes number Arₚ, and the Froude number Fr, which are dimensionless quantities relating to the flow of the fluidized bed, do not change before and after coarse graining. Further, when the conversion rule of the physical property values and the physical quantities before and after the coarse graining is obtained under the condition that the void rate ε does not change and the gas viscosity coefficient μ does not change, the following conversion rule is obtained.

$${ρ}_{f 2} = \frac{1}{K \sqrt{K}} {ρ}_{f 1} \\ {ρ}_{p 2} = \frac{1}{K \sqrt{K}} {ρ}_{p 1} \\ {V}_{2} = \sqrt{K} {V}_{1} \\ {U}_{2} = \sqrt{K} {U}_{1} \\ {V}_{mf 2} = \sqrt{K} {V}_{mf 1} \qquad ( 4 )$$

From the conversion rule of the gas density ρ_{f2}, the following conversion rule is obtained for the gas pressure p.

$${p}_{2} = \frac{1}{K \sqrt{K}} {p}_{1} \qquad ( 5 )$$

Assuming that the apparent volume V_{A} of the region filled with the particles before and after coarse graining does not change and the number of particles is reduced to 1/K³ by coarse graining, the following conversion rule is obtained.

mₚ₂=(K\sqrt{K})mₚ₁ (6)

Particle mass flow rate mₚ dot is defined by the following expression, with the channel area as A.

\dot{m}ₚ=ρₚUA (7)

From this expression, the following conversion rule is derived.

$${\dot{m}}_{p 2} = \frac{1}{K} {\dot{m}}_{p 1} \qquad ( 8 )$$

Further, the condition that the dimensionless quantities relating to heat transport do not change before and after coarse graining is also added. The dimensionless quantities relating to heat transport include a Prandtl number Pr, a particle Nusselt number Nuₚ, and a Biot number Bi. The Prandtl number Pr, the particle Nusselt number Nuₚ, and the Biot number Bi are defined by the following expression.

$$Pr = \frac{μ {c}_{p , f}}{{k}_{f}} \\ {Nu}_{p} = \frac{{hD}_{p}}{{k}_{f}} \\ Bi = \frac{{hL}_{p}}{{k}_{p}} \qquad ( 9 )$$

Here, Lₚ is the characteristic length of the particle and can be defined by Lₚ=Dₚ/6.

In order to simplify the temperature dependence of the physical property values, it is assumed that the particle temperature Tₚ and the gas temperature T do not change before and after coarse graining. Further, it is assumed that the particle heat transfer coefficient h also does not change before and after coarse graining. Under this assumption, the following conversion rule is obtained.

kₚ₂=K·kₚ₁

k_{f2}=K·k_{f1}

c_{p,f2}=K·c_{p,f1} (10)

The conversion rule of the particle specific heat c cannot be determined only by the above assumptions. In the present embodiment, in order to determine the conversion rule of the particle specific heat c, the assumption that the sensible heat Q_{p,all} of all particles does not change before and after coarse graining is introduced. The sensible heat Q_{p,all} Of the all particles is defined by the following expression, where Nₚ is the number of particles and ΔTₚ is the difference between the initial temperature of the particles and the temperature T of gas introduced into the fluidized bed.

Q_{p,all}=NₚmₚcΔTₚ (11)

Since the number Nₚ of particles is reduced to about 1/K³ by coarse graining, assuming that the sensible heat Q_{p,all} of the all particles is in variable before and after coarse graining, the following conversion rule is obtained.

c₂=(K\sqrt{K})c₁ (12)

The heat transfer amount Q dot on the surface of the particle is defined by the following expression.

\dot{Q}=hAₛ(T−Tₚ) (13)

From this definition, the following conversion rule is obtained for the heat transfer amount Q dot.

\dot{Q}₂=K²\dot{Q}₁ (14)

The following conversion rule is obtained for the heat flux q dot on the particle surface.

\dot{q}₂=\dot{q}₁ (15)

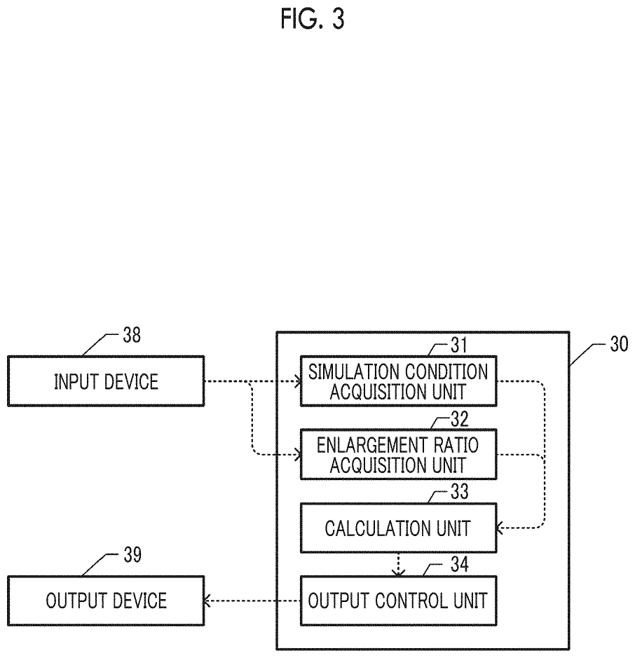

FIG. 3 is a block diagram of the simulation device according to the present embodiment. The simulation device according to the present embodiment includes a processing device 30, an input device 38, and an output device 39. The processing device 30 includes a simulation condition acquisition unit 31, an enlargement ratio acquisition unit 32, a calculation unit 33, and an output control unit 34.

Each block shown in FIG. 3 can be realized by an element such as a central processing unit (CPU) of a computer or a mechanical device in terms of hardware, and by a computer program or the like in terms of software. FIG. 3 shows functional blocks realized by cooperation of hardware and software. Therefore, these functional blocks can be realized in various modes by a combination of hardware and software.

A processing device 30 is connected to an input device 38 and an output device 39. The input device 38 receives input of commands and data from a user related to the processes executed by the processing device 30. As the input device 38, for example, a keyboard or a mouse for receiving input by user's operation, a communication device for receiving input via a network such as the Internet, a reading device for receiving input from a recording medium such as a CD or a DVD can be used.

The simulation condition acquisition unit 31 acquires the simulation condition via the input device 38. The simulation condition includes various types of information necessary for the simulation. For example, physical property values of particles and gases to be simulated, initial conditions of physical quantities relating to particles and gases, boundary conditions, or the like are included. The enlargement ratio acquisition unit 32 acquires the enlargement ratio K (FIG. 2) through the input device 38.

The calculation unit 33 calculates the initial conditions of the physical property values and physical quantities of particles and gases after coarse graining, by multiplying the physical property values and physical quantities before coarse graining by the coefficient of coarse graining (FIG. 2), based on the simulation condition and the enlargement ratio K. A fluidized bed is simulated by coupling the CFD and the DEM, based on the initial conditions of the physical property values and the physical quantities after coarse graining.

The output control unit 34 outputs the simulation result to the output device 39. For example, changes in the position and temperature of particles and changes in the temperature distribution of gas are graphically displayed on the display screen of the output device 39.

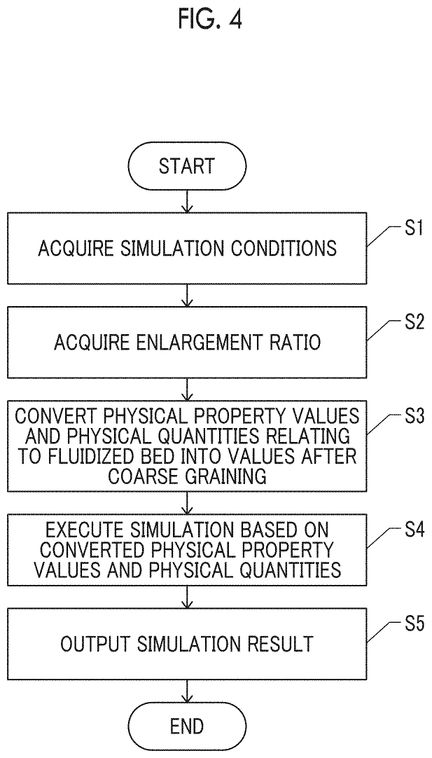

FIG. 4 is a flowchart of the simulation method according to the present embodiment. First, the simulation condition acquisition unit 31 (FIG. 3) acquires the simulation conditions (step S1), and the enlargement ratio acquisition unit 32 (FIG. 3) acquires the enlargement ratio K (FIG. 2) (step S2).

After that, the calculation unit 33 (FIG. 3) converts the initial values of the physical property values and the physical quantities which are input as the simulation conditions into the values after coarse graining (step S3). Further, simulation is executed based on the converted physical property values and physical quantities (step S4). When the simulation ends, the output control unit 34 (FIG. 3) outputs the simulation result (step S5).

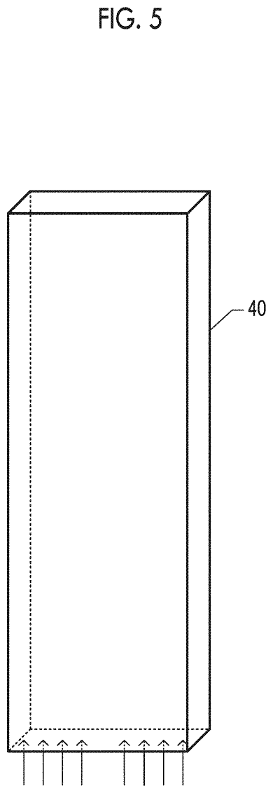

Next, with reference to FIG. 5 to FIG. 7B, the result obtained by performing actual simulation using the simulation method according to the present embodiment will be described. The target of this simulation is the same as that described in the related art.

FIG. 5 is a perspective view showing a simulation region 40. The simulation region 40 is a rectangular parallelepiped having a width of 8 cm, a thickness of 1.5 cm, and a height of 25 cm. The simulation region 40 is filled with a plurality of glass particles having a diameter of 1 mm, and gas is introduced into the simulation region 40 from the bottom surface of the simulation region 40. The particle density ρₚ was set to 2500 kg/m³. The particle specific heat c was 840 J/kg/K, the gas constant pressure specific heat c_{p,f} was 1010 J/kg/K, and the gas viscosity coefficient μ was 2.0×10⁻⁵ Pa·s. The total mass of the particles filled in the simulation region 40 was set to 75 g. A gas having a temperature lower than the initial temperature of the particles was introduced into the simulation region 40. Simulations were performed when the flow rate of gas was 1.20 m/s (when the flow rate was slow) and when the flow rate was 1.54 m/s (when the flow rate was fast).

A fluidized bed that has been coarse-grained with an enlargement ratio K as 2 and an original fluidized bed are simulated.

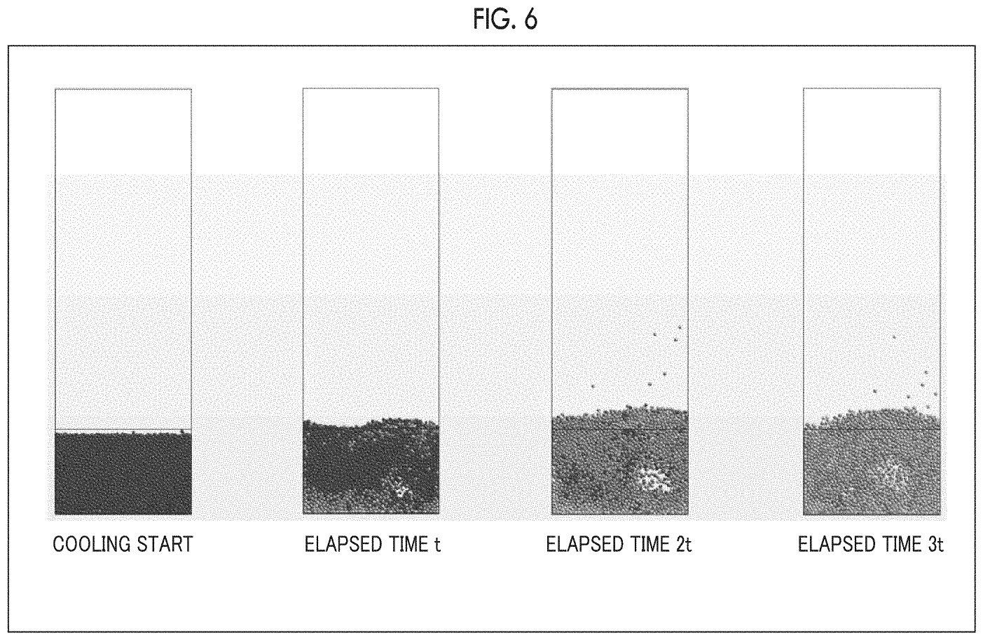

FIG. 6 is a diagram showing the position and temperature of the coarse-grained particles obtained by simulation of the coarse-grained fluidized bed in time series. The first, second, third, and fourth figures from the left in FIG. 6 show the state of the fluidized bed at the cooling start point and the elapsed times t, 2t, and 3t from the cooling start, respectively. The density of each particle represents the temperature of the particle, and the higher the temperature, the darker the density. It can be seen that the particles flow due to the inflow of gas, and the temperature of the particles decreases with the passage of time.

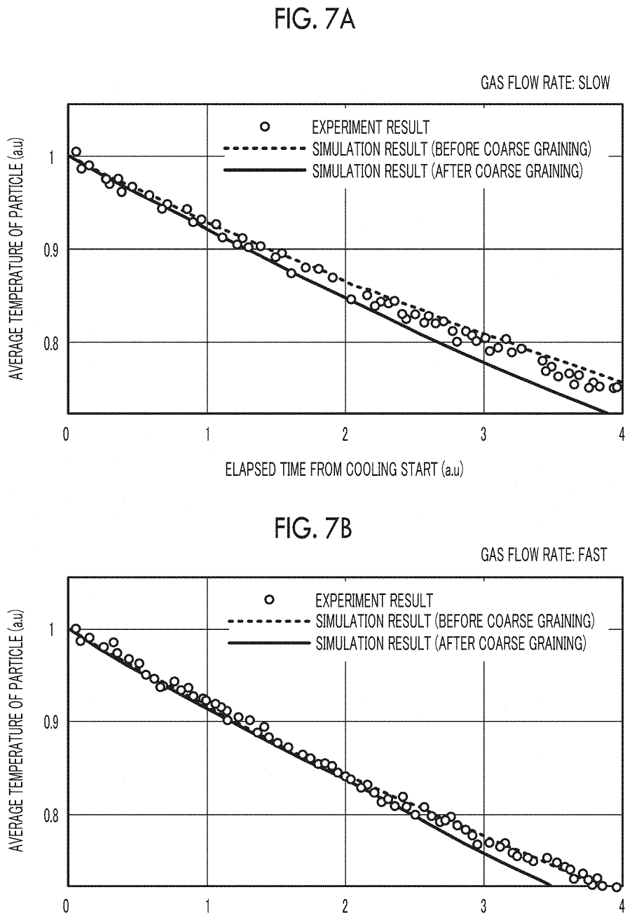

FIG. 7A and FIG. 7B are graphs showing the time change of the average temperature of the particles obtained from the simulation results. The horizontal axis represents the elapsed time from the start of cooling in any units, and the vertical axis represents the average temperature of the particles as a relative value based on the initial temperature. FIG. 7A shows a case where the gas flow rate is slow, and FIG. 7B shows a case where the gas flow rate is fast. The broken line in the graph shows the simulation result of the fluidized bed before coarse graining, and the solid line shows the simulation result of the fluidized bed after coarse graining. For reference, the temperature changes in the particles according to the experimental results shown in the related art are indicated by circle symbols.

From the simulation results shown in FIGS. 7A and 7B, it can be confirmed that the simulation results are well consistent with the experiment results even when the simulation is performed by coarse graining with the method according to the present embodiment. It can also be confirmed that when the gas flow rate is increased, the temperature decrease of the particles is accelerated. As described above, the coarse graining method according to the present embodiment can be applied to the simulation of the behavior of the fluidized bed accompanied by the temperature change.

By performing the coarse graining, the calculation time required for the simulation became about ⅓ of that of the fluidized bed simulation before the coarse graining. In this way, the coarse graining can reduce the calculation load.

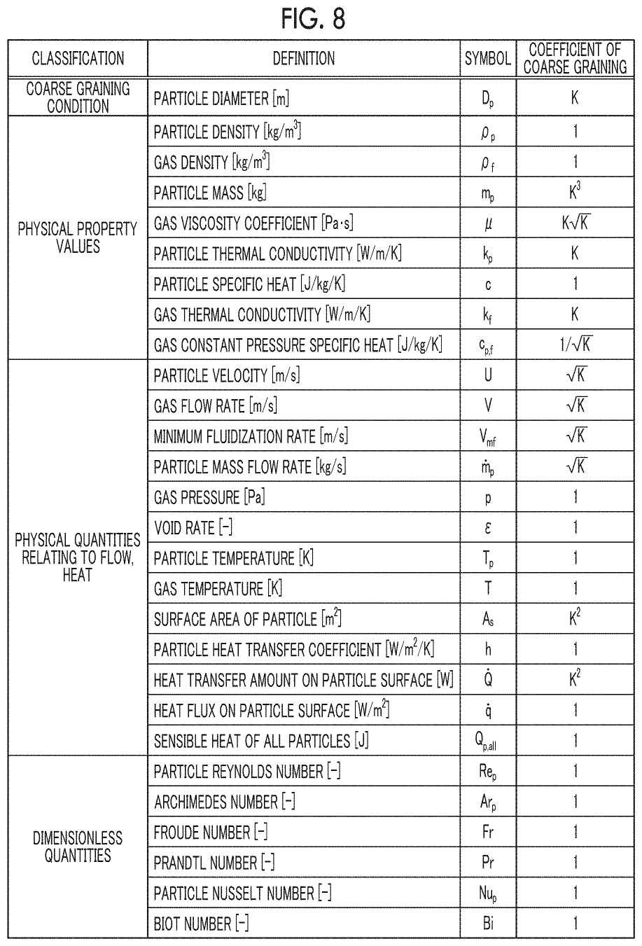

Next, with reference to FIG. 8, a conversion rule for physical property values and physical quantities according to another embodiment will be described.

FIG. 8 is a chart showing a conversion rule applied in the simulation method according to the present embodiment. Hereinafter, a description will be made while comparing with the conversion rule shown in FIG. 2.

The dimensionless quantity relating to the flow of the fluidized bed and the dimensionless quantity relating to heat transport do not change before and after the coarse graining, as in the case of the embodiment shown in FIG. 2. The fact that the particle temperature Tₚ, the gas temperature T, and the particle heat transfer coefficient h do not change before and after coarse graining is similar to the case of the embodiment shown in FIG. 2.

In the embodiment shown in FIG. 2, it is assumed that the gas viscosity coefficient μ does not change before and after coarse graining, but in the present embodiment, it is assumed that the particle density ρₚ and the gas density ρ_{f} do not change before and after coarse graining. Under this assumption, assuming that the sensible heat Q_{p,all} Of the all particles does not change before and after coarse graining, the particle specific heat c also does not change before and after coarse graining. Further, the gas pressure p does not change before and after coarse graining.

In the embodiment shown in FIG. 8, the conversion rule of the particle mass mₚ, the gas viscosity coefficient μ, the particle specific heat c, the gas constant pressure specific heat c_{p,f}, and the particle mass flow rate mₚ dot is different from the conversion rule shown in FIG. 2. Simulation may be performed by converting the physical property values and physical quantities of particles and gas using the conversion rule shown in FIG. 8.

Needless to say, each of the above-described embodiments is merely an example, and partial replacement or combination of the configurations shown indifferent embodiments is possible. The same effects by the same configurations of the plurality of embodiments will not be sequentially described for each embodiment. Further, the embodiments of the present invention are not limited to the embodiments described above. It will be apparent to those skilled in the art that various modifications, improvements, combinations, and the like can be made.

It should be understood that the invention is not limited to the above-described embodiment, but may be modified into various forms on the basis of the spirit of the invention. Additionally, the modifications are included in the scope of the invention.

What is claimed is:

1. A simulation method comprising:
performing coarse graining in which particles contained in a fluidized bed to be simulated are virtually enlarged to reduce the number of particles, the fluidized bed containing a fluid and a plurality of the particles in the fluid;
converting physical property values relating to the particles and the fluid, and physical quantities defined for the particles and the fluid, under conditions that dimensionless quantities relating to a flow of the fluidized bed and dimensionless quantities relating to heat transport do not change before and after the coarse graining; and
simulating a behavior of the fluidized bed by using the converted physical property values and physical quantities.

2. The simulation method according to claim 1, wherein the dimensionless quantities relating to the flow that do not change before and after coarse graining are a particle Reynolds number, an Archimedes number, and a Froude number.

3. The simulation method according to claim 1, wherein the dimensionless quantities relating to heat transport that do not change before and after the coarse graining are a Prandtl number, a particle Nusselt number, and a Biot number.

4. The simulation method according to claim 1, wherein the physical property values and the physical quantities are converted, under conditions that a temperature of the fluid and a temperature of the particles are invariable before and after coarse graining.

5. The simulation method according to claim 1, wherein the physical property values and the physical quantities are converted, under conditions that a heat transfer coefficient between the particles and the fluid is invariable before and after coarse graining.

6. The simulation method according to claim 1, wherein the physical property values and the physical quantities are converted, under conditions that sensible heat of all particles is invariable before and after coarse graining.

7. A simulation device comprising:
a simulation condition acquisition unit that acquires of physical property values of a fluid and particles of a fluidized bed to be simulated, and initial conditions of physical quantities defined for the fluid and the particles, the fluidized bed including the fluid and a plurality of the particles in the fluid;
an enlargement ratio acquisition unit that acquires an enlargement ratio for enlarging the particles; and
a calculation unit that converts the initial conditions of the physical quantities and the physical property values which are acquired by the simulation condition acquisition unit, and simulates a behavior of the fluidized bed by using the converted physical property values and physical quantities, under the conditions that dimensionless quantities relating to a flow of the fluidized bed and dimensionless quantities relating to heat transport do not change even when the particles are enlarged.

8. A computer readable medium storing a program that causes a computer to execute a process, the process comprising:
a function of acquiring physical property values of a fluid and particles of a fluidized bed to be simulated and initial conditions of physical quantities defined for the fluid and the particles, the fluidized bed including the fluid and a plurality of the particles in the fluid;
a function of acquiring an enlargement ratio for enlarging the particles; and
a function of converting the acquired initial conditions of the physical quantities and physical property values, and simulating a behavior of the fluidized bed by using the converted physical property values and physical quantities, under the conditions that dimensionless quantities relating to a flow of the fluidized bed and dimensionless quantities relating to heat transport do not change even when the particles are enlarged.
